(19) United States
(12) Patent Application Publication
(10) Pub. No.: US 2019/0310337 A1
(43) Pub. Date: Oct. 10, 2019

(54) METHOD AND COMPUTER FOR PRODUCING A PULSE SEQUENCE FOR CONTROLLING A MAGNETIC RESONANCE IMAGING APPARATUS

(71) Applicant: Siemens Healthcare GmbH, Erlangen (DE)

(72) Inventors: Flavio Carinci, Wuerenlingen (CH); Dominik Paul, Bubenreuth (DE); Daniel Nico Splitthoff, Uttenreuth (DE); Mario Zeller, Erlangen (DE)

(73) Assignee: Siemens Healthcare GmbH, Erlangen (DE)

(21) Appl. No.: 16/376,249

(22) Filed: Apr. 5, 2019

(30) Foreign Application Priority Data
Apr. 9, 2018 (DE) 102018205301.4

(51) Int. Cl. G01R 33/54; G01R 33/50

(52) U.S. Cl. CPC G01R 33/543; G01R 33/50

(57) ABSTRACT

In a pulse sequence that is produced and used for controlling a magnetic resonance imaging system as part of an inversion recovery measurement sequence, a number of partial volumes to be imaged are excited, wherein the pulse sequence includes a start sequence followed by an excitation sequence. The start sequence is series arrangement of a succession of at least two initial inversion pulses for inverting partial volumes. The excitation sequence is series arrangement of excitation blocks and additional inversion pulses, with each excitation block being followed by additional inversion pulses, so that excitation blocks and additional inversion pulses always alternate.

### BACKGROUND OF THE INVENTION

### Field of the Invention

The invention concerns a method and a pulse sequence generator for producing a pulse sequence for controlling a magnetic resonance imaging apparatus, as well as a corresponding control method, and a corresponding magnetic resonance imaging apparatus.

### Description of the Prior Art

Imaging systems that use a magnetic resonance measurement, detecting signals emitted by excited nuclear spins, are known as magnetic resonance imaging (MR) apparatus. Such MR apparatuses have become established and proven successful through numerous different uses. In this form of image acquisition, for the purpose of spatial resolution of the imaging signal, a rapidly switched magnetic field, known as the gradient field, is usually superimposed on a static basic magnetic field B0, which is used for the initial orientation and homogenization of magnetic dipoles (nuclear spins) under examination. In order to determine material properties of an examination subject to be imaged, the dephasing or relaxation time after the magnetization has been deflected out of the initial orientation (excitation) is ascertained in order to be able to identify different material-specific relaxation mechanisms or relaxation times. The deflection is usually performed by a number of RF pulses, and in this process the spatial resolution is based on timed manipulation of the deflected magnetization by the gradient field in what is known as a measurement sequence or pulse sequence, which defines precisely the timing of RF pulses, the change in the gradient field (by emitting a switched sequence of gradient pulses), and the acquisition of measured values. In addition to the relaxation, there are also a number of other mechanisms for creating contrast, for instance flow measurement and diffusion imaging.

An intermediate step is typically used to make an association between measured magnetization, from which the material properties can be derived, and a spatial coordinate of the measured magnetization in the spatial domain in which the subject under examination is situated. In this intermediate step, acquired magnetic resonance raw data are entered into a memory at readout points in what is known as “k-space.” The coordinates of k-space are encoded as a function of the gradient fields. The value of the magnetization (in particular of the transverse magnetization defined in a plane perpendicular to the aforementioned basic magnetic field) at a specific position in the subject under examination can be determined from the k-space data using a Fourier transform. In other words, the k-space data (magnitude and phase) are needed in order to calculate a signal strength, and, if applicable, the phase, of the signal in the spatial domain.

Magnetic resonance imaging is a type of imaging technique that proceeds relatively slowly, because the data are acquired sequentially along the trajectories, for instance rows or spirals, in Fourier space, i.e. in k-space.

A frequently used technique is to acquire images in two-dimensional slices. Compared with acquisitions in three dimensions, this is far less prone to errors because the number of encoding steps are fewer than for a three-dimensional technique. Therefore, image volumes containing stacks composed of two-dimensional slices are used in many applications instead of a single three-dimensional acquisition.

Slices (also known as “slabs”) that have been acquired as part of a magnetic resonance imaging measurement always have a finite thickness in practice, even though they are considered as (two-dimensional) surfaces. Therefore the term “partial volumes” is also used below. The expressions “partial volume” and “slice” can be considered here to be fundamentally synonymous.

In some acquisition techniques in the technical field of magnetic resonance imaging, it is desirable or necessary for magnetic resonance signals from different tissue to be suppressed by selecting a suitable inversion time TI. The inversion time TI is adapted to suit the relevant tissue. An “inversion recovery sequence” is often used in order to achieve this suppression. An “inversion recovery sequence” refers to a basic pulse sequence that is preceded by an additional 180° pulse. In terms of procedure, inversion recovery sequences are otherwise the same as the usual basic pulse sequences. Examples of such sequences are STIR sequences for suppressing fat, or FLAIR sequences for suppressing fluid. The preceding 180° pulse is also called the “inverting pulse” or “inversion pulse”, because it inverts the longitudinal magnetization of the spins in an excited area. Thus there is a longitudinal magnetization of −1 instead of 1. This causes pre-saturation.

The end of the inversion pulse is followed by a longitudinal relaxation, which leads, via the transverse plane (XY-plane), back into the initial position to a positive longitudinal magnetization. During this relaxation, the longitudinal magnetization first decreases until the vector lies in the transverse plane (where the longitudinal magnetization is 0), and from there increases again until it again equals the original longitudinal magnetization (having the value 1).

Since the longitudinal relaxation of all tissue differs, the passage of the magnetization vector through the transverse plane takes place at a different time instant in different tissues. By appropriate choice of the inversion time TI, i.e. the time that elapses between applying an inversion pulse and applying an excitation block (usually 90° for instance for a spin echo sequence), it is possible to select a specific tissue that has a longitudinal magnetization of 0 at this time instant. This tissue selected by choosing the inversion time TI does not emit any MR signal because no longitudinal vector can be flipped into the transverse plane, or in other words, the transverse magnetization corresponding to the previous longitudinal magnetization is now zero. Since the T1 time of tissues, or the necessary TI, is known, the signal from a specific tissue can be eliminated. When a long inversion time is selected, the resulting duration of the acquisition must be considered.

For the aforementioned short tau inversion recovery sequence (STIR sequence), inversion times TI of 100 ms to 150 ms are typical, although they are dependent on the B0 field strength of the main coil. For such a selection of the inversion time, there is no longitudinal magnetization present, and hence no signal emitted, at the time instant of the (90°) excitation pulse. Thus in an image acquired in this manner, fat will appear black in the image.

For the aforementioned fluid attenuated inversion recovery sequence (FLAIR sequence), inversion times typically lie in the region of more than 2000 ms (so longer than 2 seconds), again obviously dependent on the B0 field strength of the main coil. As a result of these inversion times, fluid signals (“fluid MR signals”) are suppressed and appear black in an image acquisition. A FLAIR sequence can be used to suppress the signal from the cerebrospinal fluid (CSF), for instance.

A conventional inversion recovery sequence involves a repeated, strongly alternating application of inversion pulses and excitation blocks, each in succession for the slices (partial volumes) to be acquired. The acquisition scheme is shown in FIG. 2 and described in greater detail below with examples. A disadvantage of this inversion recovery sequence is that it takes an unacceptable amount of time, for instance as part of a FLAIR sequence.

In order to shorten the scan time, another inversion scheme is normally used, which is called “interleaved inversion recovery” (IIR). In this scheme, a number of inversion pulses are applied directly in succession for different slices. The excitation blocks (and signal acquisition) for the corresponding slices are applied subsequently after the inversion time has elapsed. This results in a sequence in which groups of inversion pulses and excitation blocks, which groups act on all the slices, are always applied alternately. Such a sequence is shown in FIG. 3 and described in greater detail below.

Another inversion scheme, which constitutes a combination of the aforementioned schemes, can be used for intermediate values of TI. This is shown in FIG. 4 and described in greater detail below.

Using the latter two schemes has the serious drawback that they are sensitive to a variety of effects that can result in a contrast that varies in each of the acquired slices. The reason for this is an inhomogeneous sequence equalization.

The same applies to the excitation pulses. This results in a signal steady-state that varies in every slice, because slice crosstalk and transfer of the magnetization can affect the signal from a given slice.

Although these disadvantageous effects can also degrade conventional magnetic resonance acquisitions, they have a particularly detrimental impact on simultaneous multislice acquisitions (SMS acquisitions), because the central slice is excited together with the first slice of a slice group. This results in a contrast jump in the center of the slice group (for SMS factor=2).

### SUMMARY OF THE INVENTION

An object of the present invention is to avoid the disadvantages described above and to achieve improved acquisition of magnetic resonance images. This includes the object of providing a method and a pulse sequence generating apparatus for producing a pulse sequence, and a method for controlling a magnetic resonance imaging computer using such a pulse sequence, and a corresponding magnetic resonance imaging apparatus.

The method according to the invention is used, as is the pulse sequence generator according to the invention, to produce a pulse sequence for controlling a magnetic resonance imaging system as part of an inversion recovery measurement sequence for generating magnetic resonance image data on a subject under examination, in which, in order to acquire magnetic resonance raw data, different transverse magnetizations are excited in a plurality of partial volumes to be imaged, which in particular are arranged parallel to one another, and are used for the imaging.

The fundamental nature of an inversion recovery measurement sequence is known to those skilled in the art. In particular, pulse sequences that have a long inversion time, e.g. FLAIR sequences, are of special interest for the method according to the invention.

A pulse sequence within the meaning of the invention always relates to a sequence within a repetition or concatenation, i.e. a sequence for acquiring a specific number of partial volumes. As part of the generation of magnetic resonance image data, it is possible here to cycle through a plurality of inversion recovery measurement sequences, in which the partial volumes are repeatedly acquired (repetition) and/or in which different sets of partial volumes are acquired (concatenation).

For better understanding, the pulse sequence is divided below into two theoretical segments, into a “start sequence” and an “excitation sequence”, with the excitation sequence always following the start sequence and comprising, if applicable, repetitions of sub-sequences. As explained in greater detail below, the excitation sequence comprises excitation blocks and inversion pulses. An excitation block can contain one or more excitation and/or refocusing pulses and additionally also gradient pulses.

The method according to the invention includes the following steps.

In a first step, the start sequence is formed by series arrangement of a succession of at least two initial inversion pulses for inverting partial volumes. Thus at the start of the pulse sequence there are no excitation blocks for exciting these partial volumes. Disregarding any possible gradients or pulses for controlling parameters that are not relevant to the core of the invention, then essentially only inversion pulses lie in the start sequence, and no data acquisition takes place.

The term “initial inversion pulse” denotes an inversion pulse that inverts the spins of a partial volume for the first time. In contrast, the term “successor inversion pulse” is used for an inversion pulse that inverts a partial volume again. Normally, initial inversion pulse and successor inversion pulse are identical and differ solely in the time at which they are arranged. If there are a plurality of partial volumes, for example, then always the inversion pulse that inverts a partial volume for the first time becomes the initial inversion pulse, and those inversion pulses which, after an excitation of the partial volume concerned, invert this partial volume for a second, third, etc. time, become successor inversion pulses.

In the next step, the excitation sequence is formed by series arrangement of excitation blocks and additional inversion pulses. In this step, each excitation block is followed by additional inversion pulses, so that excitation blocks and additional inversion pulses always alternate. The additional inversion pulses may be initial inversion pulses (if a partial volume is being inverted for the first time) or successor inversion pulses.

It should be noted that the excitation sequence particularly preferably starts with an excitation block. Were it to start with an (initial) inversion pulse, then this could always be assigned to the start sequence.

As a consequence of the particular positioning in the excitation sequence, it is never possible after the first excitation block for two inversion pulses (for partial volumes relevant to the invention) to come directly one after the other. A succession of two or more inversion pulses only occurs in the start sequence.

A pulse sequence according to the invention is produced by the method according to the invention, and is used to control a magnetic resonance imaging apparatus as part of an inversion recovery for generating magnetic resonance image data on a subject under examination, in which magnetic resonance raw data is acquired, wherein different transverse magnetizations are excited in a number of partial volumes to be imaged and are used for the imaging. As described in detail above, the pulse sequence has a start sequence followed by an excitation sequence.

The pulse sequence according to the invention is structured such that:
in the start sequence, there is a series arrangement of a succession of at least two initial inversion pulses for inverting partial volumes. As already explained above, the start sequence does not contain any excitation blocks relevant to the invention;
in the excitation sequence, there is a series arrangement of excitation blocks and additional inversion pulses, with each excitation block being followed by additional inversion pulses, so that excitation blocks and additional inversion pulses always alternate. Reference is again made to the more detailed explanations above.

A pulse sequence generating computer according to the invention produces a pulse sequence according to the invention. It is designed to produce a pulse sequence having the start sequence followed by the excitation sequence described above. The pulse sequence generating apparatus is designed such that:
in the start sequence, it generates a series arrangement of a succession of at least two initial inversion pulses for inverting partial volumes, with each inversion pulse inverting a different partial volume;

and
in the excitation sequence, it generates a series arrangement of excitation blocks and additional inversion pulses, with each excitation block being followed by additional inversion pulses, so that excitation blocks and additional inversion pulses always alternate.

A control method according to the invention for controlling a magnetic resonance imaging system for generating magnetic resonance image data from a subject under examination, in which magnetic resonance raw data are acquired, wherein different transverse magnetizations are excited in a number of partial volumes to be imaged and are used for the imaging, has the following steps.
producing or providing a pulse sequence according to the invention (if applicable, produced by the method according to the invention); and
applying the pulse sequence as part of a magnetic resonance imaging acquisition executed by the magnetic resonance imaging apparatus, or the scanner thereof. As a result, the partial volumes are inverted and excited on the basis of the pulse sequence.

A controller according to the invention for controlling a magnetic resonance imaging system is designed to perform a control method according to the invention and/or has a pulse sequence generating apparatus according to the invention.

A magnetic resonance imaging system according to the invention has a controller according to the invention.

Most of the aforementioned components of the apparatus and/or of the controller can be implemented in full or in part in the form of software modules in a processor of a suitable apparatus or controller. An implementation largely in software has the advantage that even apparatuses and/or controllers already in use can be easily upgraded by a software update in order to work in the manner according to the invention.

The present invention also encompasses a non-transitory, computer-readable data storage medium encoded with programming instructions that, when the storage medium is loaded into a pulse generating computer, or a computer or computer system of a magnetic resonance apparatus, cause the pulse generating computer or the magnetic resonance computer or computer system to implement any or all embodiments of the method according to the invention, as described above.

Individual features of different exemplary embodiments or variants in the detailed description below can also be combined to create new exemplary embodiments or variants.

The pulse sequence preferably has an inversion time TI (necessary for an examination) between the first initial inversion pulse and the first excitation block. This inversion time TI is longer than the sum of the time length dI of this inversion pulse (or even of another inversion pulse, because the dl of the inversion pulses are usually the same) and the time length dE of an excitation block. It preferably holds here that:

TI>3/2dI+dE. (1)

Preferably, the inversion time TI is first compared with a preset time limit before producing a pulse sequence, and thereafter it is determined how the pulse sequence must be produced. The time limit G can be formed, for instance, from the right-hand part of the above equation (1), G=3/2dI+dE.

If the inversion time TI is longer than the preset time limit, a pulse sequence according to the invention is formed (in accordance with the method according to the invention).

If the inversion time TI is shorter than the preset time limit, a pulse sequence is produced in which each inversion pulse for a partial volume is followed by an excitation block for this partial volume without an inversion pulse or an excitation block for another partial volume being arranged between these two, and with the pairs of inversion pulses and excitation blocks for the partial volumes to be acquired being arranged next to one another.

Thus for short inversion times, a pulse sequence that differs from the invention would be used, and the pulse sequence according to the invention would be used only for longer inversion times. The pulse sequence according to the invention is appropriate whenever the inversion time becomes so long that the alternative pulse sequence no longer has any advantages in terms of the measurement length.

If an absolute time is considered, then particularly preferably the inversion time TI is greater than 1000 ms.

Depending on the usage, it is preferred to determine the number P of initial inversion pulses in the start sequence on the basis of the time length dI of the inversion pulses, the time length dE of the excitation blocks, and the inversion time TI. In this case, this number P is preferably determined as follows:

P=int (TI−dI/2)/(dI+dE)]+1. (2)

The pulse sequence preferably has at least three initial inversion pulses in the start sequence. In particular, the number of initial inversion pulses in the start sequence equals the number of groups of the partial volumes to be inverted, so that there are no longer any initial inversion pulses in the excitation sequence but just successor inversion pulses.

Alternatively, depending on the usage, it is preferred that in the excitation sequence of the pulse sequence is arranged at least one initial inversion pulse after the first excitation block. In this alternative, the start sequence thus does not include all the initial inversion pulses (and particularly preferably also does not include any successor inversion pulses, because an excitation is meant to take place between a repeated inversion of a slice).

The pulse sequence is preferably structured such that with regard to the partial volumes, the order of the excitation blocks always matches the order of the inversion pulses. This means that the partial volume that has been inverted by the first initial inversion pulse is excited as the first, the second inverted partial volume is also excited as the second, and so on.

It is particularly preferred for a partial volume to always already have been inverted first before it is excited, i.e. between a first excitation block and a second excitation block for a partial volume is always positioned a successor inversion pulse for this partial volume.

This can be explained most clearly using indexing, which corresponds to the order in time of the inversion (and the excitation). Each pulse having a certain indexing (e.g. “1”) acts on the same partial volume. The spatial arrangement and excitation of the partial volumes are not considered here. The indices relate solely to time aspects. The indexing of the partial volumes thus relates to the order in which they are inverted and/or excited. In this example, an initial inversion pulse 1 for inverting the partial volume1 is arranged first in the pulse sequence, followed by an initial inversion pulse 2 for inverting the partial volume2 (and by additional initial inversion pulses if applicable). This would correspond to the start sequence. Then follows the excitation sequence, which is led by the excitation block 1. An inversion pulse follows this excitation block 1. What inversion pulse this is depends on the start sequence. If there were three partial volumes (1, 2, 3), and if all the initial inversion pulses (1, 2, 3) were to lie in the start sequence, then the successor inversion pulse 1 would be arranged after the excitation block 1, and then the excitation block 2 would follow. If there were three partial volumes (1, 2, 3), and if only two initial inversion pulses (1, 2) were to lie in the start sequence, then in this case the initial inversion pulse 3 would be arranged after the excitation block 1, and then the excitation block 2 would follow.

If an SMS (simultaneous multislice) acquisition technique is meant to be used for the magnetic resonance imaging acquisition, then a plurality of partial volumes are excited simultaneously. In the aforementioned example, all the partial volumes excited simultaneously would have the same index because, of course, the indices relate to the order in time.

The method can be used either with or without SMS, although the main advantage of time reduction is particularly apparent with SMS. In the case of an SMS acquisition technique, all the pulses (inversion, excitation and possibly refocusing) should be multiband pulses.

A preferred control method includes comparing the inversion time with a preset time limit, which time limit is preferably determined from the pulse repetition time, the time length of an inversion pulse, the time length of an excitation block, and in particular the number of inversion pulses to be arranged initially in the start sequence.

If the inversion time TI is longer than the preset time limit, a pulse sequence according to the invention is formed (in accordance with the method according to the invention).

If the inversion time TI is shorter than the preset time limit, a pulse sequence is produced in which each inversion pulse for a partial volume is followed by an excitation block for this partial volume without an inversion pulse or an excitation block for another partial volume being arranged between these two, and with said pairs of inversion pulses and excitation blocks for the partial volumes to be acquired being arranged next to one another (see FIG. 2).

The number P of (initial) inversion pulses in the start sequence is obtained preferably on the basis of the time length dI of the initial inversion pulses, the time length dE of the excitation blocks, and the inversion time TI. In this case, this number P is particularly preferably determined according to equation (2) above.

### BRIEF DESCRIPTION OF THE DRAWINGS

FIG. 1 is a schematic diagram of a magnetic resonance imaging system according to an exemplary embodiment of the invention.

FIG. 2 shows a pulse sequence according to the prior art.

FIG. 3 shows another pulse sequence according to the prior art.

FIG. 4 shows a third pulse sequence according to the prior art.

FIG. 5 shows a procedure for forming a pulse sequence according to the prior art.

FIG. 6 shows an exemplary embodiment of a pulse sequence according to the invention.

FIG. 7 shows another exemplary embodiment of a pulse sequence according to the invention.

FIG. 8 shows an exemplary embodiment of a pulse sequence according to the invention in the form of a sequence table.

FIG. 9 shows another exemplary embodiment of a pulse sequence according to the invention in the form of a sequence table.

FIG. 10 shows an example of a procedure for forming a pulse sequence according to the invention.

### DESCRIPTION OF THE PREFERRED EMBODIMENTS

Highly simplified diagrams are used below to depict pulse sequences. For a better understanding of the invention, the various pulses are shown in some cases as a function of time t on a common time base, or in a table. Normally in a pulse diagram of a gradient echo sequence, the radio-frequency pulses (RF pulses) to be emitted and the gradient pulses are shown on different time axes lying one above the other. Usually, the RF pulses are shown on a radio-frequency-pulse time axis, and the gradient pulses are shown on three gradient-pulse time axes, which correspond to three spatial directions. Thus, for instance, as regards their amplitudes, readout-gradient pulses can be allotted to the three gradient axes, and hence be oriented in space as required.

The following figures show elements that are essential to the invention or helpful to understanding the invention.

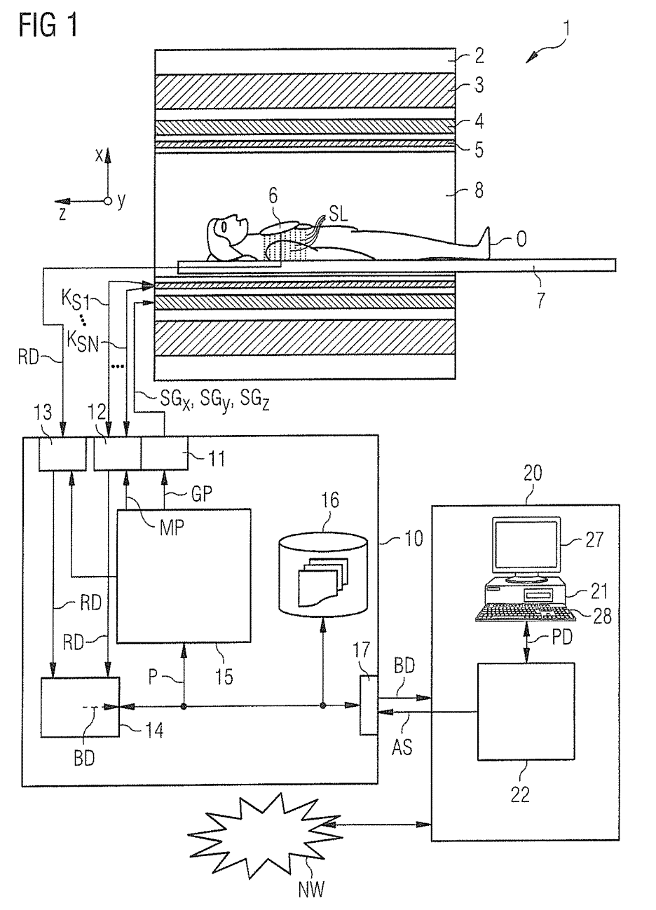

FIG. 1 shows a simplified diagram of a magnetic resonance imaging system 1 according to the invention. It includes the actual magnetic resonance scanner 2 containing therein a measurement space 8 or patient tunnel. A bed 7 can be moved into this patient tunnel 8, so that a subject under examination O (for instance patient/person under examination or a material under examination) lying thereon can be supported during an examination in a specific position inside the magnetic resonance scanner 2 relative to the magnet system and radio-frequency system arranged therein and can also be moved between different positions during a measurement.

Essential components of the magnetic resonance scanner 2 are a basic field magnet 3, a gradient coil system 4 composed of gradient coils for applying required magnetic field gradients in the x-, y- and z-directions, and a radio-frequency body coil 5. Alternatively or additionally, local transmit RF coils can also be used for exciting magnetic resonance signals, as is often the case when imaging the knee, for example.

Magnetic resonance signals induced in the subject under examination O can be received via the body coil 5, which is normally also used to emit the radio-frequency signals for inducing the magnetic resonance signals. Usually, however, these signals are received using local coils 6 placed on or under the subject under examination O. All these components are generally known to those skilled in the art and are therefore only shown in outline in FIG. 5.

The radio-frequency body coil 5, for instance in the form of what is known as a birdcage antenna, can comprise a number N of individual antenna rungs, which can be controlled separately as individual transmit channels K₁, . . . , K_{N} by a controller 10, i.e. the magnetic resonance imaging system 1 is a pTX-compliant system. The method according to the invention can also be applied to traditional magnetic resonance imaging systems having just one transmit channel.

The controller 10 may be a control processor, which can also consist of a multiplicity of individual processors, which may also be spatially separate and interconnected via suitable bus systems or cables or the like. This controller 10 is connected via a terminal interface 17 to a terminal 20, by means of which an operator can control the entire magnetic resonance imaging system 1. In the present case, this terminal 20 has a computer 21 having keyboard 28, one or more screens 27, and further input devices such as a mouse or the like, for instance, so that the user is provided with a graphical user interface.

The controller 10 includes, inter alia, a gradient controller 11, which itself can be formed by multiple subcomponents. The individual gradient coils are switched by control signals SGx, SGy, SGz by means of this gradient controller 11. This involves gradient pulses, which during a measurement are set at precisely designated positions in time and with a precisely defined time waveform, in order to scan the subject under examination O and the associated k-space preferably in individual slices SL in accordance with a pulse sequence PS.

The controller 10 also includes a radio-frequency transceiver 12. This RF transceiver 12 likewise is composed of multiple subcomponents in order to emit radio-frequency pulses separately and in parallel onto each of the transmit channels K₁, . . . , K_{N}, i.e. in this case into the individually controllable antenna rungs of the body coil 5. Magnetic resonance signals can also be received via the transceiver 12. In this exemplary embodiment, however, this is done using the local coils 6. The raw data RD received by these local coils 6 are read out and processed by an RF receiver 13. The magnetic resonance signals received thereby or by the body coil 5 via the RF transceiver 12 are passed as raw data RD to a reconstruction computer 14, which reconstructs therefrom the image data BD, and stores the image data in a memory 16 and/or transfers this image data via the interface 17 to the terminal 20, so that the image data can be viewed by the operator. The image data BD can also be stored and/or displayed and analyzed in other places via a network NW. If the local coils 6 have a suitable switchover unit, they can also be connected to the RF transceiver 12 in order to use the local coils as well for transmitting, in particular in pTX mode.

The gradient controller 11, the RF transceiver 12 and the receiver 13 for the local coils 6 are each coordinated in a measurement controller 15. This measurement controller uses suitable commands to ensure that a desired gradient pulse train GP is emitted by suitable gradient control signals SGx, SGy, SGz, and to control the RF transceiver 12 in parallel such that a multichannel pulse train MP is emitted, i.e. such that on the individual transmit channels K₁, . . . , K_{N}, the appropriate radio-frequency pulses are placed in parallel onto the individual transmit rungs of the body coil 5. It is also necessary to ensure that at the right time instant, the RF receiver 13 reads out and processes further the magnetic resonance signals at the local coils 6, and that the RF transceiver 12 reads out and processes further any signals that may be at the body coil 5. The measurement controller 15 defines the relevant signals, in particular the multichannel pulse train MP to the radio-frequency transceiver 12 and the gradient pulse train GP to the gradient controller 11, in accordance with a predetermined control protocol. This control protocol holds all the control data that must be set during a measurement in accordance with a predetermined pulse sequence PS.

Usually the memory 16 holds a multiplicity of control protocols for different measurements. These could be selected and, if applicable, altered, by the operator via the terminal 20, in order then to have available for the currently required measurement a suitable control protocol with which the measurement controller 15 can work. Furthermore, the operator can also retrieve control protocols via a network NW, for instance from a manufacturer of the magnetic resonance system, and then, if necessary, modify and use these control protocols.

Those skilled in the art are familiar with the basic procedure for such a magnetic resonance measurement and the control components mentioned, however, so they are not discussed further here in detail. Moreover, the magnetic resonance scanner 2 and the associated controller can also comprise a multiplicity of further components that are not described in detail here either. It must be mentioned here that the magnetic resonance scanner 2 may also have a different design, for instance may have a patient chamber that is open at the side, and that in principle the radio-frequency body coil need not be in the form of a birdcage antenna.

FIG. 1 also shows schematically a pulse sequence generating apparatus 22, which is used for producing a pulse sequence PS. This pulse sequence PS contains, inter alia, for a specific measurement, a pulse train GP in order to make a specific trajectory in k-space, and a radio-frequency pulse train coordinated therewith, in this case a multichannel pulse train MP, for controlling the individual transmit channels K₁, . . . , K_{N}.

In the present case, the pulse sequence PS is produced on the basis of the method according to the invention. The pulse sequence generating apparatus 22 may here be comprised by the magnetic resonance imaging system 1 and be part of the terminal 20 or in particular even part of the controller 10. It is also possible, however, for the pulse sequence generating apparatus 22 to exist externally as an independent unit and to be designed for use with a plurality of different magnetic resonance systems.

The descriptions given above make it clear that the invention provides effective means of improving in terms of speed, flexibility and image quality, a method for controlling a magnetic resonance imaging system for generating magnetic resonance image data.

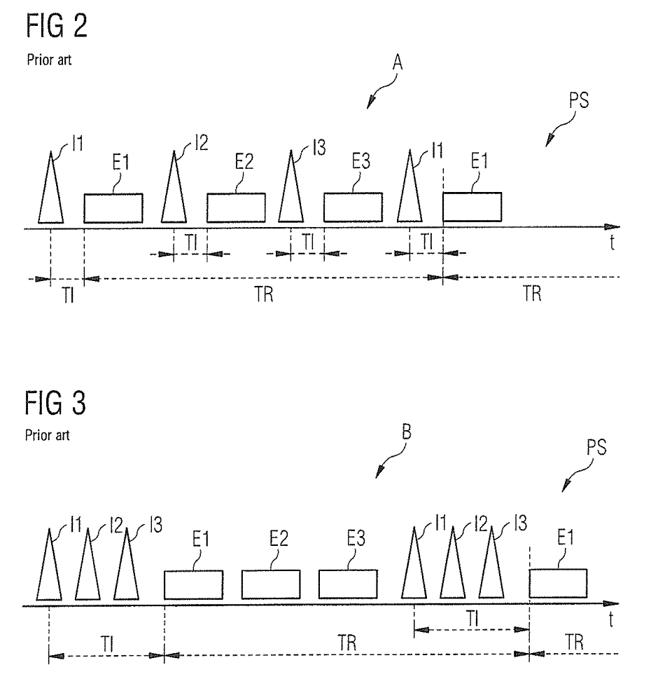

FIGS. 2, 3 and 4 show pulse sequences according to the prior art as outlined briefly in the introductory part of the description.

FIG. 2 shows a pulse sequence in the form of an inversion recovery sequence A. First is applied a first inversion pulse I1 for inverting a first slice (group), followed by a first excitation block E1 after the inversion time TI. Then a second inversion pulse 12 for inverting a first second slice (group) is applied, followed by a second excitation block E1 after the inversion time TI. Then follow, as applicable, third, fourth and fifth passes. When all the passes have been made, the first pulse repetition time TR is over and the pulse sequence is repeated.

In this case, the minimum pulse repetition time TR would be given by TR=(TI+dE+dI/2)·n, where dI is the time length of an inversion pulse I1, I2, I3; dE is the time length of an excitation block E1, E2, E3; and n is the number of slices to be excited.

FIG. 3 shows a pulse sequence based on the principle of Interleaved Inversion Recovery B. First is applied a group of inversion pulses I1, I2, I3 for inverting all the slices or (slice groups), followed by a group of excitation blocks E1, E2, E3 for exciting all the slices. In this case, the first excitation block E1 is applied after the inversion time TI after the first inversion pulse I1. Thereafter, the first pulse repetition time TR is over and the pulse sequence is repeated. This sequence has the advantage that all the inversion pulses I1, I2, I3 can be applied within a single inversion time TI. This reduces the minimum pulse repetition time TR to the value TR=(TI+dE·n+dI/2).

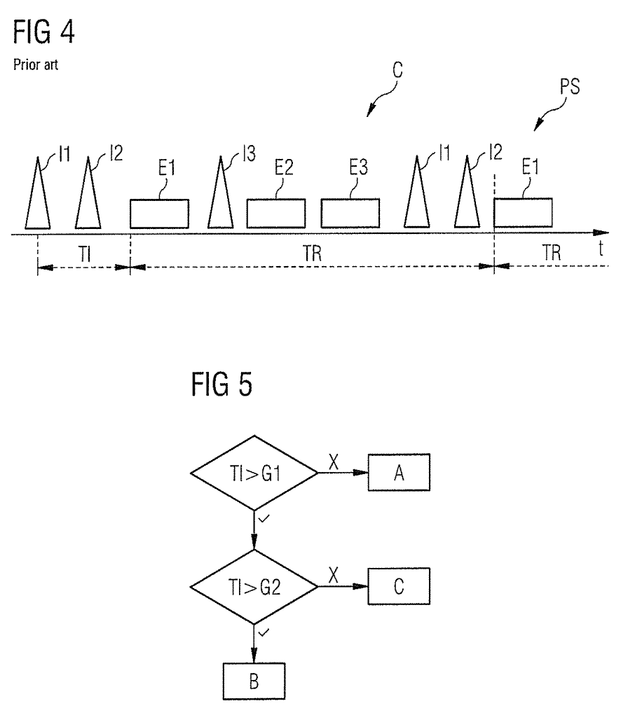

FIG. 4 shows a pulse sequence based on a scheme C for intermediate values of TI. First are applied two inversion pulses I1, I2 for inverting two slices (or slice groups), so that the second inversion pulse I2 is applied after the inversion pulse I1 within the inversion time TI. Thereafter, a first excitation block E1 is applied, followed by a third inversion pulse I3. This is followed by two excitation blocks E2, E3, and finally again the first two inversion pulses I1, I2. The first pulse repetition time TR is then over and the pulse sequence is repeated. In case C, the minimum pulse repetition time TR is given by TR=TI+dE·n+dI/2+dI·(n−P), where P is the number of inversion pulses applied initially.

FIG. 5 shows a procedure for forming a pulse sequence PS according to the prior art. In this procedure, before producing the pulse sequence PS, the inversion time TI is first compared with a preset first time limit G1 of value 3/2 dI+dE, where dI is the time duration of an inversion pulse, and dE is the time length of an excitation block.

If the inversion time TI is shorter than the time limit, a pulse sequence PS is produced in accordance with the aforementioned scheme A, as depicted in FIG. 2.

Thereafter is performed another comparison of the inversion time TI with a preset second time limit G2 of value max [(n−1/2)dI, dI/2+(n−1)dE], where n is the number of slices (or slice groups).

If the inversion time TI is shorter than this second time limit, a pulse sequence PS is produced in accordance with the aforementioned scheme C, as depicted in FIG. 4.

If the inversion time TI is longer than this time limit, a pulse sequence PS is produced in accordance with the aforementioned scheme B, as depicted in FIG. 3.

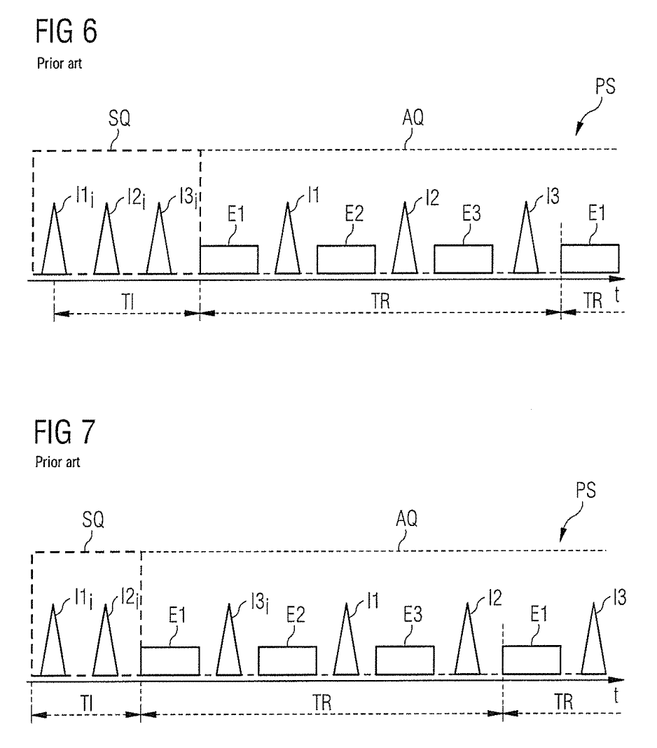

FIG. 6 shows an exemplary embodiment of a pulse sequence PS according to the invention. The pulse sequence PS has a start sequence SQ and an excitation sequence AQ, which follows the start sequence SQ and is repeated. The pulse sequence PS has the following structure in this case:

In the start sequence SQ, three initial inversion pulses I1ᵢ, I2ᵢ, I3ᵢ for inverting three partial volumes S1, S2, S3 are arranged in series, consecutively in time. It is assumed in this example that only three partial volumes (slices) exist, and therefore a succession of all the initial inversion pulses I1ᵢ, I2ᵢ, I3 ᵢ is present in the start sequence SQ.

In the excitation sequence AQ is applied a series arrangement of excitation blocks E1, E2, E3 and additional successor inversion pulses I1, I2, I3, with each excitation block E1, E2, E3 being followed by additional successor inversion pulses I1, I2, I3, so that excitation blocks E1, E2, E3 and successor inversion pulses I1, I2, I3 always alternate.

The time interval between two successive inversion pulses I1ᵢ, I1 for a partial volume S1 is given by the pulse repetition time TR. The same applies to two successive excitation blocks E1 for a partial volume. An inversion pulse I1 can certainly be created more than an excitation block E1 (i.e. follow said excitation block) in order to fill the entire acquisition homogeneously.

The indexing here corresponds to the order in time, i.e. using an inversion pulse I1 for a given partial volume S1 cannot be repeated before an excitation block E1 has been used for this partial volume S1. This means that in order to achieve larger values of TI, a larger number of partial volumes S1, S2, S3, S4 must be acquired, or alternatively, the intervals between inversion pulses I1, I2, I3, I4 and excitation blocks E1, E2, E3, E4 must be increased.

The example in FIG. 6 differs from the example in FIG. 2 not only in terms of the specific order of the pulses but in the fundamental structure of the pulse sequence PS. In the pulse sequence PS according to the invention, more than one single inversion pulse I1 is arranged at the start of the pulse sequence. The pulse sequence PS according to the invention differs from the examples in FIGS. 3 and 4 in that there is a strongly alternating succession of excitation blocks E1, E2, E2 and inversion pulses I1, I2, I3.

FIG. 7 shows another exemplary embodiment of a pulse sequence PS according to the invention. Unlike FIG. 6, in this case instead of there being a succession of all the initial inversion pulses I1ᵢ, I2ᵢ, I3ᵢ in the start sequence SQ, initial inversion pulses I3ᵢ are actually applied in the excitation sequence AQ. Unlike the examples in FIGS. 3 and 4, however, there is again in this case a strongly alternating succession of excitation blocks E1, E2, E2 and inversion pulses I1, I2, I3.

This pulse sequence PS has the advantage that compared with the previous example, it can also be used with shorter inversion times TI.

The minimum pulse repetition time TR is (TI+dE+dI/2)*(n−P+1), where n is the number of partial volumes to be excited (or slice groups when a number of partial volumes are excited simultaneously) and P is the number of (initial) inversion pulses I1ᵢ, I2ᵢ, I3ᵢ in the start sequence SQ (P=2 in this example).

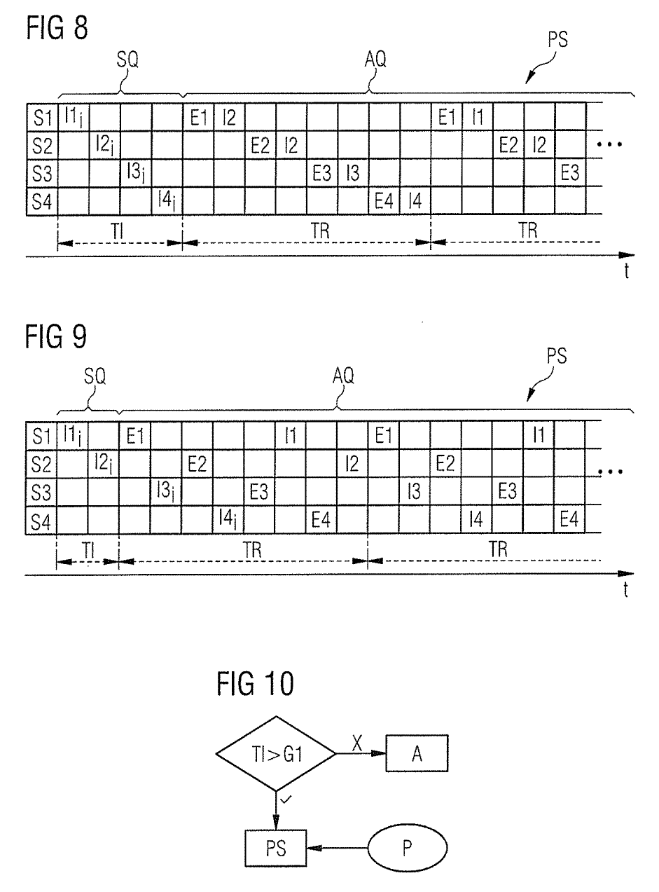

FIGS. 8 and 9 show exemplary embodiments of pulse sequences PS according to the invention in the form of sequence tables. The arrangement is shown here for four partial volumes S1, S2, S3, S4, which correspond to four slices SL in FIG. 1.

FIG. 8 follows the principle of FIG. 6. In this case, all the initial inversion pulses I1ᵢ, I2ᵢ, I3ᵢ , I4ᵢ, are arranged in the start sequence SQ. In the excitation sequence AQ is applied a series arrangement of excitation blocks E1, E2, E3, E4 and additional successor inversion pulses I1, I2, I3, I4, with each excitation block E1, E2, E3, E4 being followed by additional successor inversion pulses I1, I2, I3, I4, so that excitation blocks E1, E2, E3, E4 and successor inversion pulses I1, I2, I3, I4 always alternate. The time sequence of the arrangement, i.e. of application, is always made from 1 to 4.

FIG. 9 follows the principle of FIG. 7. In this case, only two initial inversion pulses I1ᵢ, I2ᵢ, are arranged in the start sequence SQ. The other initial inversion pulses I3ᵢ, I4ᵢ are applied in the excitation sequence AQ. Again in this case, the arrangement/application always takes place from 1 to 4, and therefore the two initial inversion pulses I3ᵢ, I4ᵢ must be arranged/applied first before the first successor inversion pulse IL Once again, however, there is a strongly alternating succession of excitation blocks E1, E2, E3, E4 and inversion pulses in the excitation sequence.

FIG. 10 shows a preferred procedure for forming a pulse sequence PS according to the invention. In this procedure, before producing the pulse sequence PS, the inversion time TI is first compared with a preset time limit G1 of value 3/2 dI+dE, where dI is the time length of an inversion pulse, and dE is the time length of an excitation block.

If the inversion time TI is longer than this time limit G1, a pulse sequence PS according to the invention, as depicted in FIG. 6 or 7 for example, is formed. The number P of initial inversion pulses I1ᵢ, I2ᵢ, I3ᵢ , I4ᵢ in the start sequence is obtained here using the formula P=int[(TI−dI/2)/(dI+dE)]+1.

If the inversion time TI is shorter than the time limit, a pulse sequence PS is produced in accordance with the aforementioned scheme A, as depicted in FIG. 2.

It should be reiterated that the method described in detail above and the presented magnetic resonance imaging apparatus 1 are merely exemplary embodiments, which can be modified by a person skilled in the art in many ways without departing from the scope of the invention. In addition, the use of the indefinite article “a” or “an” does not rule out the possibility of there also being more than one of the features concerned. Likewise, the terms “unit” and “module” do not exclude the possibility that the components in question consist of a number of interacting sub-components, which may also be spatially distributed if applicable.

Although modifications and changes may be suggested by those skilled in the art, it is the intention of the Applicant to embody within the patent warranted hereon all changes and modifications as reasonably and properly come within the scope of the Applicant's contribution to the art.

1. A method for producing a pulse sequence for controlling a magnetic resonance imaging apparatus as part of an inversion recovery measurement sequence for generating magnetic resonance image data on a subject under examination, in which, in order to acquire magnetic resonance raw data, different transverse magnetizations are excited in a plurality of partial volumes to be imaged, and are used for the imaging, wherein the pulse sequence comprises a start sequence followed by an excitation sequence, said method comprising:
forming the start sequence in a computer by series arrangement of a succession of at least two initial inversion pulses for inverting partial volumes; and
forming the excitation sequence in said computer by series arrangement of excitation blocks and additional inversion pulses with each excitation block being followed by additional inversion pulses, so that excitation blocks and additional inversion pulses always alternate.

2. The method as claimed in claim 1, wherein the pulse sequence has an inversion time TI between the first initial inversion pulse and the first excitation block, wherein the inversion time TI is longer than the sum of the time length of an inversion pulse and the time length of an excitation block.

3. The method as claimed in claim 1, comprising, in said computer:
comparing the inversion time TI with a preset time limit before producing the pulse sequence;
if the inversion time TI is longer than the preset time limit, forming said pulse sequence; and
if the inversion time TI is shorter than the preset time limit, producing pulse sequence in which each inversion pulse for a respective partial volume is followed by an excitation block for that respective partial volume, without an inversion pulse or an excitation block for another partial volume being between said inversion pulse ad said excitation pulse of that respective partial volume, and with said pairs of inversion pulses and excitation blocks respectively for the partial volumes to be acquired being next to one another.

4. The method as claimed in claim 1, comprising determining a number P of initial inversion pulses in the start sequence based on a time duration dl of the inversion pulses, a time duration dE of the excitation blocks, and the inversion time TI, as
P=int[(TI−dI/2)/(dI+dE)]+1.

5. The method as claimed in claim 1, comprising generating the pulse sequence with the start sequence comprising at least three initial inversion pulses.

6. The method as claimed in claim 1, comprising generating the pulse sequence with the excitation sequence comprising at least one initial inversion pulse that occurs after the first excitation block.

7. The method as claimed in claim 1, comprising generating the pulse sequence with the start sequence comprising at least three initial inversion pulses, and with the excitation sequence comprising at least one initial inversion pulse that occurs after the first excitation block.

8. The method as claimed in claim 1, wherein a plurality of partial volumes are excited simultaneously for the magnetic resonance imaging acquisition, and wherein the inversion pulses and/or the excitation blocks comprise multiband pulses.

9. The method as claimed in claim 1, comprising generating the pulse sequence so that, with regard to the partial volumes, an order of the excitation blocks always matches an order of the inversion pulses.

10. A computer for producing a pulse sequence for controlling a magnetic resonance imaging apparatus as part of an inversion recovery measurement sequence for generating magnetic resonance image data on a subject under examination, in which, in order to acquire magnetic resonance raw data, different transverse magnetizations are excited in a plurality of partial volumes to be imaged, and are used for the imaging, wherein the pulse sequence comprises a start sequence followed by an excitation sequence, said computer comprising:
a processor configured to form the start sequence by series arrangement of a succession of at least two initial inversion pulses for inverting partial volumes; and
said processor being configured to form the excitation sequence in said computer by series arrangement of excitation blocks and additional inversion pulses with each excitation block being followed by additional inversion pulses, so that excitation blocks and additional inversion pulses always alternate.

11. A method for operating a magnetic resonance apparatus comprising:
producing a pulse sequence for controlling said magnetic resonance imaging apparatus as part of an inversion recovery measurement sequence for generating magnetic resonance image data on a subject under examination, in which, in order to acquire magnetic resonance raw data, different transverse magnetizations are excited in a plurality of partial volumes to be imaged, and are used for the imaging, wherein the pulse sequence comprises a start sequence followed by an excitation sequence;
forming the start sequence in a computer by series arrangement of a succession of at least two initial inversion pulses for inverting partial volumes; and
forming the excitation sequence in said computer by series arrangement of excitation blocks and additional inversion pulses with each excitation block being followed by additional inversion pulses, so that excitation blocks and additional inversion pulses always alternate.

12. The method as claimed in claim 11, comprising, in said computer:
comparing the inversion time TI with a preset time limit before producing the pulse sequence;
if the inversion time TI is longer than the preset time limit, forming said pulse sequence; and
if the inversion time TI is shorter than the preset time limit, producing pulse sequence in which each inversion pulse for a respective partial volume is followed by an excitation block for that respective partial volume, without an inversion pulse or an excitation block for another partial volume being between said inversion pulse ad said excitation pulse of that respective partial volume, and with said pairs of inversion pulses and excitation blocks respectively for the partial volumes to be acquired being next to one another.

13. A magnetic resonance (MR) imaging apparatus comprising:
an MR data acquisition scanner;
a computer configured to produce a pulse sequence for controlling said MR data acquisition scanner as part of an inversion recovery measurement sequence for generating magnetic resonance image data on a subject under examination, in which, in order to acquire magnetic resonance raw data, different transverse magnetizations are excited in a plurality of partial volumes to be imaged, and are used for the imaging, wherein the pulse sequence comprises a start sequence followed by an excitation sequence;
said computer being configured to form the start sequence by series arrangement of a succession of at least two initial inversion pulses for inverting partial volumes; and
said computer being configured to form the excitation sequence by series arrangement of excitation blocks and additional inversion pulses with each excitation block being followed by additional inversion pulses, so that excitation blocks and additional inversion pulses always alternate.

14. A non-transitory, computer-readable data storage medium encoded with programming instructions for producing a pulse sequence for controlling a magnetic resonance imaging apparatus as part of an inversion recovery measurement sequence for generating magnetic resonance image data on a subject under examination, in which, in order to acquire magnetic resonance raw data, different transverse magnetizations are excited in a plurality of partial volumes to be imaged, and are used for the imaging, wherein the pulse sequence comprises a start sequence followed by an excitation sequence, said storage medium being loaded into a computer and said programming instructions causing said computer to:
form the start sequence in a computer by series arrangement of a succession of at least two initial inversion pulses for inverting partial volumes; and
form the excitation sequence in said computer by series arrangement of excitation blocks and additional inversion pulses with each excitation block being followed by additional inversion pulses, so that excitation blocks and additional inversion pulses always alternate.
